(19) United States
(12) Patent Application Publication
(10) Pub. No.: US 2024/0429089 A1
(43) Pub. Date: Dec. 26, 2024

(54) ADJUSTABLE EDGE RING TILT FOR EDGE OF WAFER SKEW COMPENSATION

(71) Applicant: Applied Materials, Inc., Santa Clara, CA (US)

(72) Inventors: Peter MURAOKA, Santa Clara, CA (US); Sumanth BANDA, San Jose, CA (US); Andreas SCHMID, Meyriez (CH); Sunil SRINIVASAN, San Jose, CA (US); Paul Z. WIRTH, Kalispell, MT (US)

(21) Appl. No.: 18/212,672

(22) Filed: Jun. 21, 2023

(51) Int. Cl. H01L 21/687; G05B 15/02; H01J 37/32; H01L 21/3065

(52) U.S. Cl. CPC H01L 21/68785; G05B 15/02; H01J 37/32642; H01L 21/3065; H01L 21/68721; H01J 2237/1502

(57) ABSTRACT

Embodiments described herein generally related to a substrate processing chamber and a method of processing substrate in a processing chamber. In one embodiment, a method of using a process kit for a substrate processing chamber disclosed herein. The method begins by positioning the substrate on a substrate support disposed in the substrate processing chamber. A plasma is formed above the substrate and a tilt and height of an edge ring is adjusted with a controller. The controller is coupled to a movement assembly having one of three linear actuators for tilting a sliding ring interfaced with the edge ring to change a direction of ions at one edge of the substrate.

### BACKGROUND

### Field

Embodiments described herein generally relate to a substrate processing apparatus, and more specifically to an improved process kit for a substrate processing apparatus.

### Description of the Related Art

As semiconductor technology nodes advanced with reduced size device geometries, substrate edge critical dimension uniformity requirements become more stringent and affect die yields. Commercial plasma reactors (i.e., processing chambers) include multiple tunable knobs for controlling process uniformity across a substrate, such as, for example, temperature, gas flow, RF power, and the like. Typically, in etch processes, silicon substrates are etched while being electrostatically clamped to an electrostatic chuck.

During processing, a substrate resting on a substrate support may undergo a process that deposits material on the substrate and to remove, or etch, portions of the material from the substrate, often in succession or using cyclical processes. It is typically beneficial to have uniform deposition and etching rates across the surface of the substrate. However, process non-uniformities often exist across the surface of the substrate and may be more pronounced at the perimeter or edge of the substrate. These non-uniformities at the perimeter may be attributable to electric field termination affects and are sometimes referred to as edge effects. During deposition or etching, a process kit containing at least a deposition ring is sometimes provided to mitigate edge effects and favorably influence uniformity at the substrate perimeter or edge.

Accordingly, there is a need for an improved process kit for a substrate processing chamber.

### SUMMARY

Embodiments described herein generally related to a substrate processing chamber and a method for processing a substrate in a processing chamber. In one embodiment, a method of using a process kit for a substrate processing chamber disclosed herein. The method begins by positioning the substrate on a substrate support disposed in the substrate processing chamber. A plasma is formed above the substrate and a tilt and height of an edge ring is adjusted with a controller. The controller is coupled to a movement assembly having one of three linear actuators for tilting a sliding ring interfaced with the edge ring to change a direction of ions at one edge of the substrate.

In another embodiment, a process kit for a processing chamber is disclosed herein. The process kit has an edge ring configured to circumscribe a substrate in a semiconductor processing chamber. A sliding ring is positioned beneath the edge ring. The sliding ring has a top surface configured to contact a bottom surface of the edge ring. An actuating mechanism interfaces with a bottom surface of the sliding ring. The actuating mechanism has a first linear actuator, a second linear actuator, and a third linear actuator equally spaced along the bottom surface of the sliding ring. The actuating mechanism is configured to move the sliding ring such that the edge ring may be tilted. The actuating mechanism is configured to interface with a controller configured to independently operate the first linear actuator, the second linear actuator, and the third linear actuator. The actuating mechanism is configured to move the first linear actuator with respect to the second linear actuator to effect a tilt to the sliding ring and the edge ring for adjusting process skew in response to an algorithm for correcting process skew.

In another embodiment, a processing chamber is disclosed herein. The processing chamber has a controller configured to operate the processing chamber and a substrate support assembly. The substrate support assembly is configured to support a substrate. The substrate support assembly has a substrate support. The substrate support has a body with an electrode embedded therein. The substrate support assembly has a cathode disposed below the substrate support. The cathode configured to receive power from a waveform generator. A process kit is supported by the substrate support. The process kit has an edge ring configured to circumscribe the substrate in the semiconductor processing chamber. A sliding ring is positioned beneath the edge ring. The sliding ring has a top surface configured to contact a bottom surface of the edge ring. An actuating mechanism interfaces with a bottom surface of the sliding ring. The actuating mechanism has a first linear actuator, a second linear actuator, and a third linear actuator equally spaced along the bottom surface of the sliding ring. The actuating mechanism is configured to move the sliding ring such that the edge ring may be tilted. The actuating mechanism interfaces with the controller. The controller is configured to independently operate the first linear actuator, the second linear actuator, and the third linear actuator, wherein the first linear actuator is moved with respect to the second linear actuator to effect a tilt of the sliding ring and the edge ring for adjusting process skew in response to an algorithm for correcting process skew.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a cross sectional view of a processing chamber, according to one embodiment.

FIG. 1B is enlarged partial cross sectional view of a portion of the substrate support of FIG. 1A, according to one embodiment.

FIGS. 2A and 2B are a simplified cross sectional view of a portion of the processing chamber of FIG. 1A, according to one embodiment, illustrating a sliding ring of the present disclosure.

FIG. 3 illustrates a top view of the sliding ring.

FIG. 4 illustrates two examples for moving the sliding ring.

FIG. 5 is a flow diagram of a method for processing a substrate.

For clarity, identical reference numerals have been used, where applicable, to designate identical elements that are common between figures. Additionally, elements of one embodiment may be advantageously adapted for utilization in other embodiments described herein.

### DETAILED DESCRIPTION

Embodiments of the disclosure generally include methods and apparatuses that improve the etch rate uniformity across a surface of a substrate by controlling the shape of a plasma sheath formed across a substrate, such as a semiconductor wafer, during plasma processing. Embodiments of the disclosure enable the adjustment of one or more plasma processing variables and/or the adjustment of the configuration of process kit hardware that is in close proximity to a substrate and/or supports the substrate during processing. Thus, the uniformity of the plasma sheath across the substrate surface can be controlled, thereby increasing substrate processing yield.

The disclosed apparatus and method utilize independent motor control to set a tilt angle of the edge ring (relative to horizontal) to tune a plasma sheath for mitigating process skew. The tilt angle and optionally the height (relative to the surface supporting the substrate) of the edge ring can be selected to compensate for azimuthal non-uniformity at the edge of the substrate. The tilt angle and optional height compensates for skew at the extreme edge of the substrate due to the substrate and the edge ring being one or more of non-concentric or non-parallel, and/or the edge ring having uneven erosion. The angle and height of the ring can be set using motors or other type of actuators that adjust height and/or angle of the edge ring. In one example, three or more motors used for independently lifting the edge ring at separate locations around ring, thus allowing the tilt angle, the orientation of ring inclination, and/or height of the edge ring to be selected in a manner that would offset a known azimuthal non-uniformity of processing on the substrate, i.e., process skew. Additionally, an algorithm is provided to automate the selection of the tilt angle, the orientation of ring inclination, and/or height of the edge ring for maintaining good process uniformity.

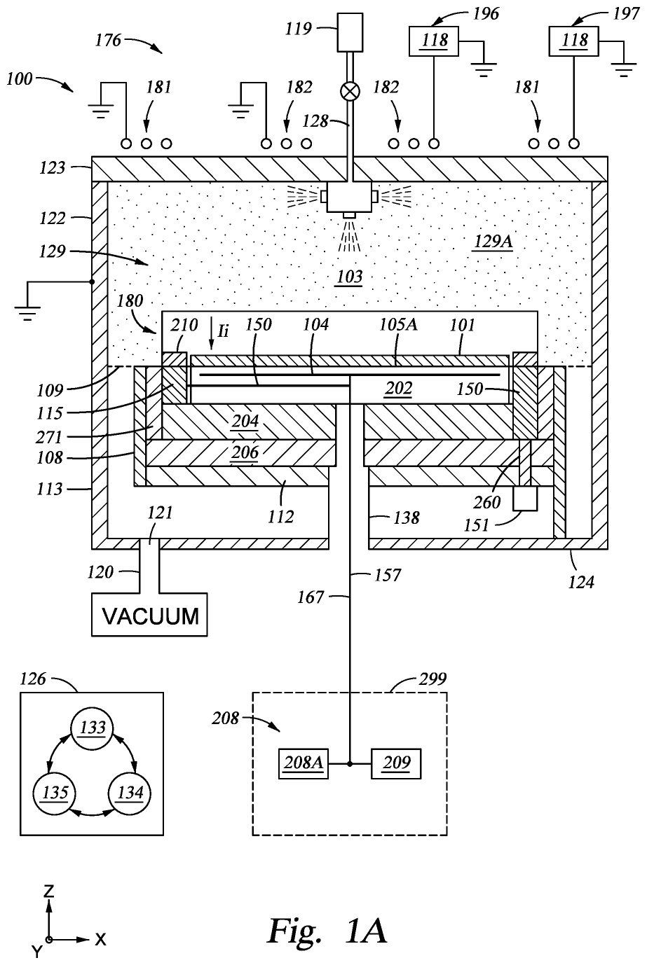

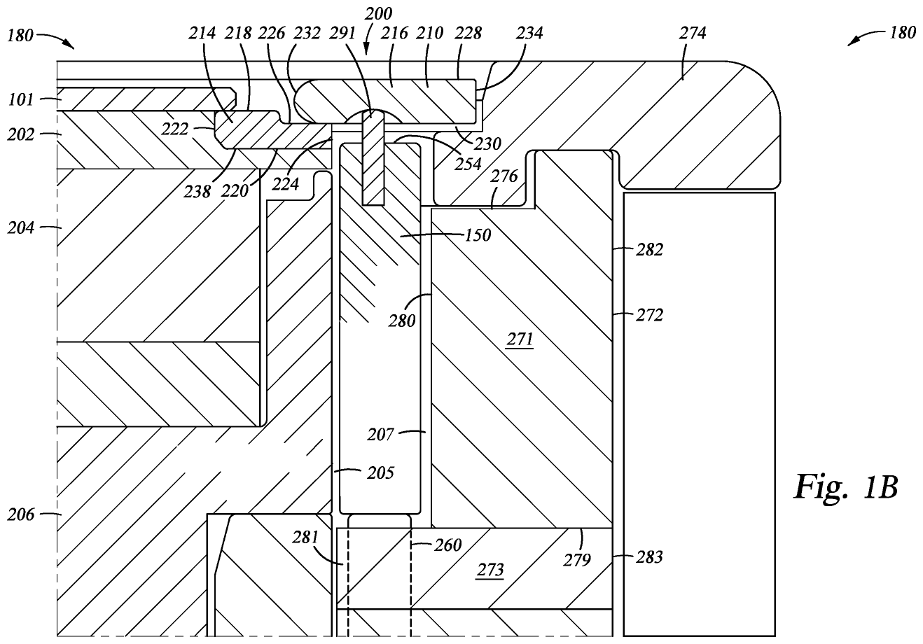

FIG. 1A is a cross sectional view of a processing chamber 100 having a sliding ring 150, according to one embodiment. As shown, the processing chamber 100 is an etch chamber suitable for etching a substrate, such as substrate 101. Examples of processing chambers that may be adapted to benefit from the disclosure are SYM3® processing chamber, and CENTURA® etch processing chamber, commercially available from Applied Materials, Inc., located in Santa Clara, California. It is contemplated that other processing chamber, including deposition chambers and those from other manufacturers, may be adapted to benefit from the disclosure.

The processing chamber 100 may be used for various plasma processes. In one embodiment, the processing chamber 100 may be used to perform dry etching with one or more etching agents. In one example, a plasma is formed in the processing chamber from a processing gas, such as CₓF_{y} (where x and y can be different allowed combinations), O₂, NF₃, or combinations thereof.

The processing chamber 100 has a chamber body 113 and a system controller 126. The chamber body 113 includes a lid assembly 176, a support assembly 136 one or more sidewalls 122 and a chamber base 124, which collectively, with a chamber lid 123 of the lid assembly 176, define the processing volume 129. A substrate support assembly 180 is disposed in the processing volume 129.

The lid assembly 176 includes the chamber lid 123 and one or more plasma source assemblies, such as two inductively coupled plasma (ICP) assemblies 196, 197. Each ICP assembly 196, 197 includes a coil 181, 182, respectively, that is configured to inductively couple a radio frequency (RF) waveform generated by a RF generator 118 to a plasma 103 formed in the processing volume 129 of the processing chamber 100 during plasma processing. In this configuration, the chamber lid 123 includes a dielectric material that is configured to allow the fields generated by the coils 181, 182 during the power delivered from the RF generator 118 to help generate and sustain the plasma 103 in the processing volume 129.

The one or more sidewalls 122 and chamber base 124 generally include materials that are sized and shaped to form the structural support for the elements of the processing chamber 100 and are configured to withstand the pressures and added energy applied to them while the plasma 103 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy.

A gas inlet 128 is disposed through the chamber lid 123. The gas inlet 128 is used to deliver one or more processing gases to the processing volume 129 from a processing gas source 119 that is in fluid communication therewith. A substrate 101 is loaded into, and removed from, the processing volume 129 through an opening (not shown) in one of the one or more sidewalls 122, which is sealed with a slit valve (not shown) during plasma processing of the substrate 101.

A vacuum system 120 is coupled to the vacuum port 121. The vacuum system 120 may include a vacuum pump and a throttle valve (not shown). The throttle valve regulates the flow of gases through the processing chamber 100. The vacuum pump is coupled to the vacuum port 121 to vacate gases from the processing volume 129 of the processing chamber 100.

The substrate support assembly 180, disposed in the processing volume 129, is configured to support the substrate 101 for processing. The substrate support assembly 180 may be coupled to a lift mechanism (not shown) through a shaft 138 which extends through the chamber base 124 of the chamber body 113. The lift mechanism may be flexibly sealed to the chamber body 113 by a bellows that prevents vacuum leakage from around the shaft 138. The lift mechanism allows the substrate support assembly 180 to be moved vertically within the chamber body 113 between a lower transfer portion and one or more raised substrate processing positions.

The substrate support assembly 180 includes a substrate support 202 (electrostatic chuck), the cooling plate 204 (or cathode), and the base 206. The cooling plate 204 is disposed on the base 206. The cooling plate 204 may include a plurality of cooling channels (not shown) for circulating coolant therethrough. The cooling plate 204 may be coupled to or engaged with the substrate support 202 by an adhesive or any suitable mechanism.

The substrate support assembly 180 includes one or more lower electrodes, which are coupled to a plasma source, such as a capacitively coupled plasma (CCP) assemblies. Typically, the substrate support 202 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), yttrium oxide (Y₂O₃), mixtures thereof, or combinations thereof. In embodiments herein, the substrate support 202 further includes a bias electrode 104 embedded in the dielectric material thereof.

One or more lift pins (not shown) may be disposed through the substrate support assembly 180. The one or more lift pins are configured to extend through the substrate support 202 such that the substrate 101 may be raised off a substrate supporting surface 105A of the substrate support 202. The one or more lift pins may be activated by a lift ring or other actuator (not shown).

The cooling plate 204 is electrically isolated from the chamber base 124 by the base 206, and the ground plate 112 is interposed between the base 206 and the chamber base 124. The substrate support 202 is thermally coupled to and disposed on the cooling plate 204. In some embodiments, the cooling plate 204 is configured to regulate the temperature of the substrate support 202, and the substrate 101 disposed on the substrate support 202, during substrate processing.

The processing chamber 100 may include a biasing assembly 299 that can include one or more plasma source assemblies that are each adapted to deliver an asymmetric voltage waveform to one or more electrodes and/or one or more coils disposed within the processing chamber 100. The one or more lower electrodes can include a bias electrode 104 and/or an edge electrode 115 that are formed within the substrate support 202, and are coupled to one or more plasma source assemblies, such as a capacitively coupled plasma (CCP) assembly. A first CCP assembly 208 may be coupled by a transmission line 157/167 to the bias electrode 104. The first CCP assembly 208 may be coupled through a conductive tube 167 to the edge electrode 115. The CCP assembly 208 is configured to deliver a waveform generated by a waveform generator, such as waveform generator 208A to the plasma 103 formed in the processing volume 129 of the processing chamber 100 during plasma processing. In one embodiment, the first waveform generator 208A of the first CCP assembly 208 is configured to bias both the bias electrode 104 and the edge electrode 115. In one example, the sliding ring 150 is the edge electrode 115. The edge electrode may have RF or DC power coupled thereto for shaping the plasma sheath. The first CCP assembly 208 may couple to the sliding ring 150 through the cooling plate 204. For example, RF power may transmit between the sliding ring 150 through the cooling plate 204. In another example DC power may couple across the cooling plate 204 to the sliding ring 150. It is contemplated that the first CCP assembly 208 may alternately couple to the sliding ring 150 through the base 206 or by other suitable approaches.

The waveform generator 208A is configured to sustain a plasma formed in a processing region and/or control the formation of a sheath over the surface of a substrate during processing. The plasma processing methods and apparatus described herein are configured to improve the control of various characteristics of the generated plasma and control an ion energy distribution (IED) of the plasma generated ions that interact with one or more regions of a surface of a substrate during plasma processing. The ability to synchronize and control waveform characteristics, such as frequency, waveform shape and applied voltage on-time during a voltage waveform pulse, provided in each of the waveforms applied to the electrodes allows for an improved control of the generated plasma. As a result, greater precision for plasma processing can be achieved, which is described herein in more detail.

The bias electrode 104 is also used as a chucking pole to secure (i.e., chuck) the substrate 101 to the substrate supporting surface 105A of the substrate support 202 and also to bias the substrate 101 with respect to the plasma 103 using one or more of the voltage waveform biasing schemes described herein. Typically, the bias electrode 104 is formed of one or more electrically conductive parts, such as one or more metal meshes, foils, plates, or combinations thereof.

The biasing assembly 299 may also include a clamping network 209 so that a high voltage bias applied to the bias electrode 104 and/or edge electrode 115. In some embodiments, the bias electrode 104 is electrically coupled to a clamping network 209 and the edge electrode 115 is electrically coupled to a separate clamping network (not shown). The clamping network, by use of high voltage DC power source, provides a chucking voltage to the bias electrode 104 and/or edge electrode 115, such as static DC voltage between about −5000 V and about +5000 V.

In some embodiments, the edge electrode 115 is positioned below the edge of the substrate and surrounds the bias electrode 104 and/or is disposed a distance from a center of the bias electrode 104. In general, for a processing chamber 100 that is configured to process circular substrates, the edge electrode 115 is annular in shape, is made from a conductive material, and is configured to surround at least a portion of the bias electrode 104. In one embodiment, the edge electrode 115 is positioned below the edge ring 210, and is embedded in the sliding ring 150. In another embodiment, the sliding ring 150 is the edge electrode.

The waveform generator 208A is electrically coupled to the cooling plate 204 through the conductive tube 167 that is electrically coupled to an output of the waveform generator 208A. The waveform generator 208A may be a RF or DC voltage waveform generating power supply that is used to control the sheath formation over the surface of the substrate during plasma processing. The biasing assembly 299 sends the waveform to both the bias electrode 104 in the substrate support 202 and the cooling plate 204 simultaneously.

Turning additionally to FIG. 1B, FIG. 1B is enlarged partial cross sectional view of a portion of the substrate support of FIG. 1A, according to one embodiment. The process kit 200 includes an edge ring 210, a support ring 214, an outer ring 274 and the sliding ring 150. A quartz pipe 271 is disposed adjacent the sliding ring 150. Optionally, the quartz pipe 271 may be disposed on a lower quartz pipe 273. In one example, the quartz pipe 271 is formed from a non-conductive material such as quartz.

The quartz pipe 271 includes a top surface 276, an inner edge 280, and an outer edge 282. The top surface 276 of the quartz pipe 271 is substantially parallel to a bottom surface 279 of the quartz pipe 271. The inner edge 280 of the quartz pipe 271 is positioned adjacent the sliding ring 150. The outer ring 274 is disposed on the top surface 276 of the quartz pipe 271. The outer ring 274 and quartz pipe 271 are configured to remain stationary with respect to the sliding ring 150 and the edge ring 210.

The support ring 214 and the edge ring 210 are interfaced with each other such that edge ring 210 may be movable relative to support ring 214. The sliding ring 150 is positioned to move the edge ring 210 vertically up and down relative to the support ring 214. An actuating assembly 151 is coupled to and disposed below the sliding ring 150. The actuating assembly 151 may consist of pins, such as three pins, coupled to a respective three linear actuators, such that the pins contact an underside of the sliding ring 150 to move the sliding ring up and down. In one example, the actuating assembly 151 consists of three linear actuators which independently work to elevate and lower the sliding ring 150. The vertical movement of the sliding ring 150 is imparted on the edge ring 210 through contact between the sliding ring 150 and the edge ring 210 to move the edge ring up and down. Thus, the height, tilt and angle of inclination of the sliding ring 150 identically sets the height, tilt and angle of inclination of the edge ring 210.

The cooling plate 204 is disposed on the base 206. The cooling plate 204 may include a plurality of cooling channels (not shown) for circulating coolant therethrough. The cooling plate 204 may be engaged with the electrostatic chuck 202 by an adhesive or any suitable mechanism. One or more waveform generators 208A may be coupled to the cooling plate 204. The waveform generator 208A may be a RF power supply for biasing ions in the processing chamber to shape a plasma sheath 404. Alternately, the waveform generator 208A may be a pulse DC power supply for biasing ions in the processing chamber to the substrate support assembly 180 to shape the plasma sheath 404. Alternately, the waveform generator 208A may be coupled to the base 206 to turn the base 206 into a cathode. The electrostatic chuck 202 may include one or more heaters (not shown). The one or more heaters may be independently controllable. The one or more heaters enable the electrostatic chuck 202 to heat the substrate 101 from a bottom surface of the substrate 101 to a desired temperature.

As discussed above, the process kit 200 is supported on the substrate support assembly 180 and includes the edge ring 210, support ring 214, outer ring 274 and sliding ring 150. The support ring 214 and the edge ring 210 are interfaced with each other. The support ring 214 includes a top surface 218, a bottom surface 220, an inner edge 222, and an outer edge 224. The top surface 218 is substantially parallel to the bottom surface 220. The inner edge 222 is substantially parallel to the outer edge 224, and substantially perpendicular to the bottom surface 220. In some embodiments, the support ring 214 further includes a stepped surface 226. In the embodiment shown, the stepped surface 226 is formed in the outer edge 224, such that the stepped surface 226 is substantially parallel to the bottom surface 220. The stepped surface 226 defines a recess for receiving the edge ring 210. Generally, the height of the support ring 214 is limited by the height of the electrostatic chuck 202. For example, the inner edge 222 of the support ring 214 does not extend above the height of the electrostatic chuck 202. As such, the support ring 214 protects a side of the electrostatic chuck 202. In some embodiments, the substrate 101, when positioned on the electrostatic chuck 202, extends partially over the support ring 214.

The edge ring 210 has a body 216 which includes a top surface 228, a bottom surface 230, an inner edge 232, and an outer edge 234. The top surface 228 is substantially parallel to the bottom surface 230. The inner edge 232 is substantially parallel to the outer edge 234 and substantially perpendicular to the bottom surface 230. In one embodiment, edge ring 210 is interfaced with the support ring 214 via the bottom surface 230. For example, the bottom surface 230 of edge ring 210 interfaces with the stepped surface 226 in the support ring 214. In another embodiment, the edge ring 210 may further include a stepped surface (not shown). The stepped surface is formed in the inner edge 232, such that the stepped surface interfaces with the stepped surface 226 of the support ring 214. When interfaced with the support ring 214, the inner edge 232 of the edge ring 210 is spaced from the substrate 101. For example, the inner edge 232 of the edge ring 210 may be spaced between about 0.02 mm and about 0.1 mm from the substrate 101.

In one embodiment, when interfaced, the edge ring 210 and the support ring 214 forms a continuous bottom surface 238. In another embodiment, when interfaced, the support ring 214 and the edge ring 210 do not form a continuous bottom surface 238. Rather, in some embodiments, the top surface 218 of the support ring 214 may be higher than the top surface 228 of the edge ring 210. In other embodiments, the bottom surface 230 of the edge ring 210 may sit below the bottom surface 220 of the support ring 214. Thus, in some embodiments, the support ring 214 and the edge ring 210 do not form a continuous top or bottom surface.

The sliding ring 150 has a top surface 254 and a bottom surface 256. The sliding ring 150 may be formed from a conductive material, such as aluminum. The sliding ring 150 is disposed beneath the edge ring 210. For example, the sliding ring 150 is disposed beneath the edge ring 210. The sliding ring 150 contacts the bottom surface of the 238 of the edge ring 210. In one example, the sliding ring 150 has a conductive pin 291. The conductive pin 291 may extend through the top surface 218. In one example, the sliding ring 150 has three conductive pins 291 formed from SiC. The conductive pin 291 enhances the power conductance from the sliding ring 150 to the edge ring 210. Alternatively, the top of the sliding ring 150 may have a bare metal or thin layer of anodizing to make a flat contact with the edge ring 210 for improved conductivity between the sliding ring 150 and the edge ring 210.

In one embodiment, the sliding ring 150 extends down the length of the electrostatic chuck 202 and the cooling plate 204, such that the sliding ring 150 has a height substantially equal to the combined height of the electrostatic chuck 202 and the cooling plate 204.

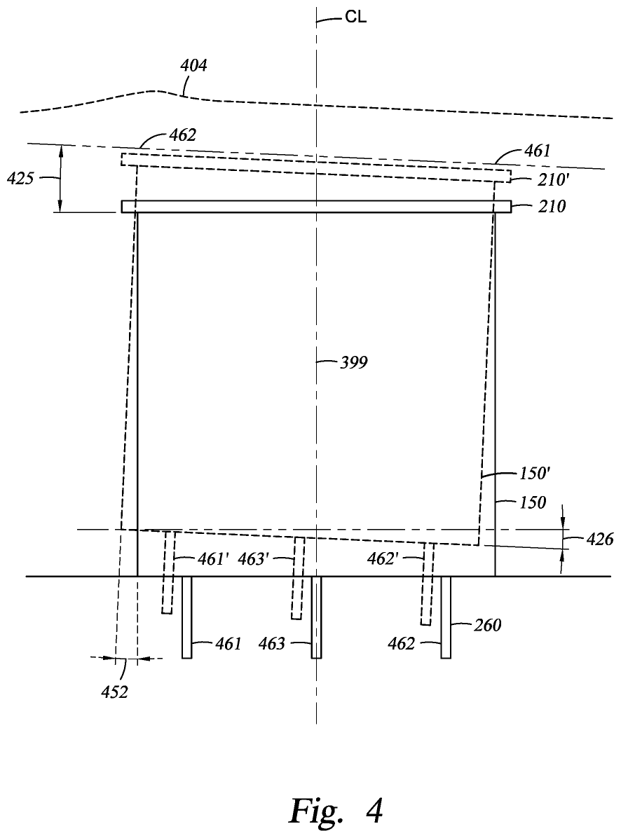

The sliding ring 150 may circumscribe the base 206, thus forming a first laterally spaced gap 205. In one example, the first laterally spaced gap 205 is greater than 0 inches and is less than or equal to 0.05 inches. The sliding ring 150 may be circumscribed by the quartz pipe 271, thus forming a second laterally spaced gap 207. In one example, the second laterally spaced gap 207 is greater than 0 inches and is less than or equal to 0.05 inches. The first laterally spaced gap 205 and the second laterally spaced gap 207 provide clearance for the sliding ring to move up and down as well as tilt relative to the substrate supporting surface 105A of the substrate support 202 (which is horizontal in this example). The tilt aspect of the sliding ring 150 will be discussed further below with respect to FIG. 4.

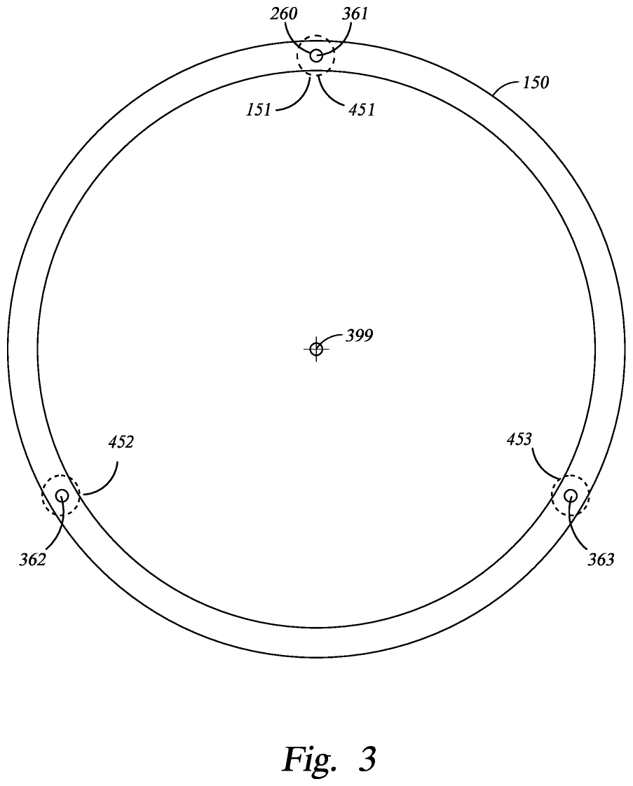

The sliding ring 150 interfaces with a plurality of spaced apart lift pins 260. In one example, the lift pins 260 are spaced equidistantly along a common radius relative to the (vertical) center line of the substrate supporting surface 105A of the substrate support 202. The lift pins 260 may be operably coupled with the sliding ring 150. The lift pins 260 may extend through a hole 281 in the lower quartz pipe 273. The lift pin 260 is driven by the actuating assembly 151. In one example, the sliding ring interfaces with three or more lift pins 260 driven by the three separate linear actuators (discussed with respect to FIG. 3 below) in the lift actuating assembly 151. The actuating assembly 151 allows the sliding ring 150 to be moved vertically within the processing chamber 100. As a result of the vertical movement of the sliding ring 150, the actuating assembly 151 raises the edge ring 210. The edge ring 210 may be raised above the support ring 214, thus forming a gap between the stepped surface of the support ring 214 and the stepped surface of the edge ring 210. The movement of the sliding ring 150 may be controlled by the controller 126.

The system controller 126, also referred to herein as a processing chamber controller, operates to control the operations of processing system 100. For example, the system controller 126 may control the operations of the biasing assembly 299 and sliding ring 150. The system controller 126 includes a central processing unit (CPU) 133, a memory 134, and support circuits 135. The system controller 126 is used to control the process sequence used to process the substrate 101, including the substrate biasing methods described herein. The CPU 133 is a general-purpose computer processor configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing chamber 100. Typically, the software program, which is readable by CPU 133 in the system controller 126, includes code, which, when executed by the processor (CPU 133), performs tasks relating to the plasma processing methods described herein.

The program may include instructions that are used to control the various hardware and electrical components within the processing chamber 100 to perform the various process tasks and various process sequences used to implement the methods described herein. In one example, the controller is configured to move the first actuating assembly with respect to the second actuating assembly to effect a tilt to the sliding ring 150 and the edge ring 210 for adjusting process skew in response to an algorithm.

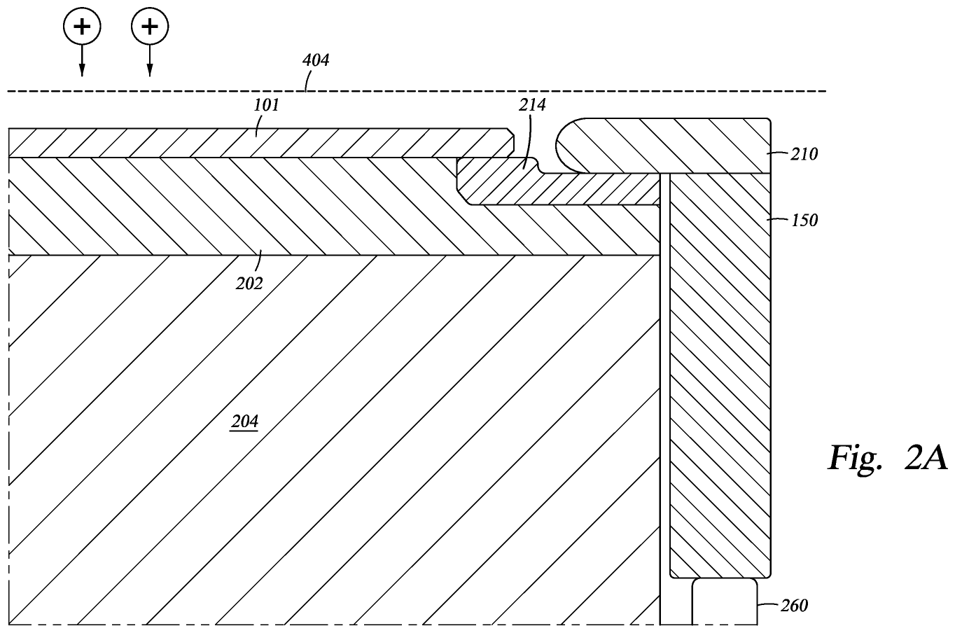

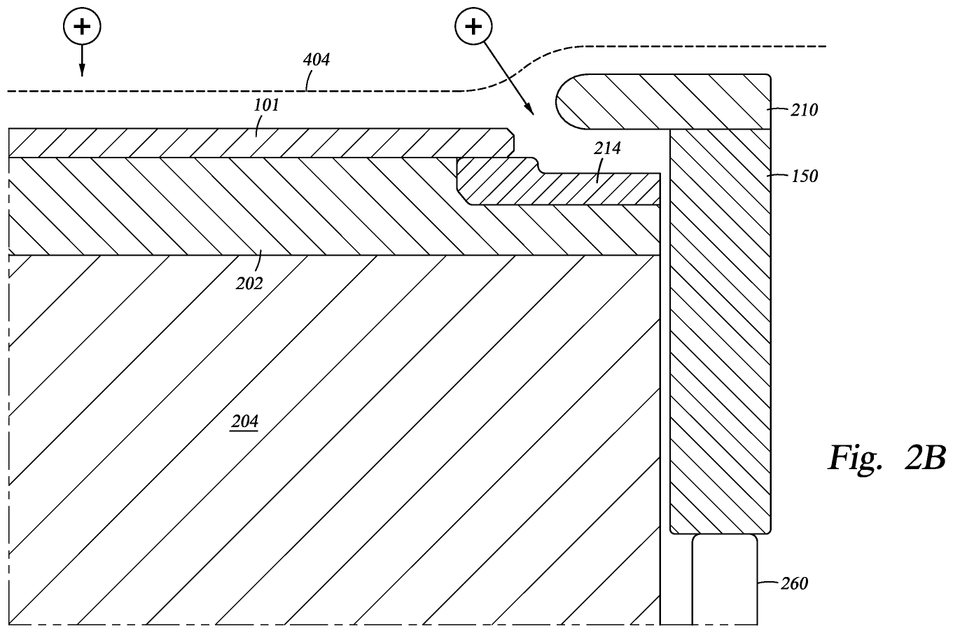

Turning to FIGS. 2A and 2B, FIGS. 2A and 2B are a simplified cross sectional view of a portion of the processing chamber of FIG. 1A, according to one embodiment, illustrating a sliding ring of the present disclosure. The substrate support assembly 180 includes a process kit 200 supported on the substrate support assembly 180.

Maintaining constant RF power applied to the edge ring 210 allows for control of a plasma sheath 404 about the substrate 101 and the edge ring 210. Voltage (V_{DC}), or RF, can be used to control the plasma sheath 404 profile at an edge of the substrate 101 to compensate for critical dimension uniformity at the edge of the substrate 101. The plasma sheath 404 is a thin region of strong electric fields formed by space charge that joins the body of the plasma to its material boundary. Mathematically, the sheath thickness, d, is represented by the Child-Langmuir equation:

$$d = \frac{2}{3} {( \frac{ε}{i} )}^{\frac{1}{2}} {( \frac{2 e}{m} )}^{\frac{1}{4}} {( {V}_{p} - {V}_{DC} )}^{\frac{3}{4}}$$

Where i is the ion current density, ε is the permittivity of vacuum, e is the elementary electric charge, Vₚ is the plasma potential, and V_{DC} is the DC voltage. In the case of an etch reactor, a plasma sheath 404 is formed between the plasma and the substrate 101 being etched, the chamber body 102, and every other part of the processing chamber 100 in contact with the plasma. The ions produced in a plasma are accelerated in the plasma sheath and move perpendicular to the plasma sheath. Controlling the V_{DC}, i.e., controlling the voltage applied to the edge ring 210, affects the thickness, d, of the sheath 404. The sheath thickness, d, of sheath 404 may be measured with respect to the edge ring 210. For example, the thickness, d, is depicted in FIGS. 2A and 2B. In the embodiment shown, the actuating assembly 151 moves the sliding ring 150 upward to raise the edge ring 210. Because V_{DC} remains constant, the sheath thickness above the edge ring 210 remains constant. Therefore actuating the sliding ring 150 vertically raises the sheath 404 without impacting the sheath thickness. Thus, moving the sliding ring 150 affects the shape of the sheath 404 at the substrate 101 edge 406, which in turn controls the direction of plasma ions.

FIG. 2B illustrates the portion of the processing chamber 100 of FIG. 2A, with the edge ring 210 in the raised position. As illustrated, and as discussed in FIG. 2A, raising the sliding ring 150 raises the edge ring 210, which in turn raises the sheath 404. Because the potential, V_{DC}, remains nearly constant as a result of a nearly fixed capacitance 302, the sheath 404 thickness, d, remains constant throughout.

FIG. 3 illustrates a top view of the sliding ring 150. The sliding ring 150 has a ring shaped body. The sliding ring 150 is supported on the pins 260 (also shown as pins 361, 362, 363 in FIG. 3). The actuating assembly 151 is configured to move the pins 260. The movement of the pins 260 raises and lowers the sliding ring 150. The actuating assembly 151 has a first linear actuator 451, a 2^{nd} linear actuator 452, and 3^{rd} linear actuator 453. The first linear actuator 451 has a first pin 361. The 2^{nd} linear actuator 452 has a 2^{nd} pin 362. The 3^{rd} linear actuator 453 has 3^{rd} pin 360. Each of the first pin 361 2^{nd} pin 362 and 3^{rd} pin 363 is equally spaced along the bottom of the sliding ring 150. In one example the first pin 361 and the 2^{nd} pin 362 are located 120 degrees from this entrance, where the 3^{rd} pin 363 may be located hundred 20° from the first pin 361 and the 2^{nd} pin 362.

Turning to FIG. 4, FIG. 4 illustrates two examples for moving the sliding ring 150. Each of the first linear actuator 451, 2^{nd} linear actuator 452, and 3^{rd} linear actuator are configured to operate independently of each other. For example, the first linear actuator 451 may receive instructions for moving the first pin 461 upward to a position as shown by 461′ while the 2^{nd} linear actuator 452 and or the 3^{rd} linear actuator 453 receive instructions to remain still, i.e., without movement, so that the pins associated with the actuators neither extend or retract. This has the effect of tilting the sliding ring 150 at an angle 425. In one example, the angle 425 may be between about 0.4° and about 2.8°. The angle 425 of the tilt may be dependent on tolerances and temperatures. For example, when the sliding ring 150 is tilted, the bottom may be displaced a distance 432. The angle 425 of the tilt is configured to sufficiently small such that distance 432 remain smaller gap 205 or gap 207. In this way, the sliding ring 150 does not have interference with the base 206, the cooling plate 204, or the quartz pipe 271. Additionally, by selecting which pin 361, 362, 363 moves relative to the other pins 361, 362, 363, the orientation of the inclination can be selected in addition to the height and tilt of the sliding ring 150, and consequently the edge ring 210, can be controlled.

The tilt of the sliding ring 150 has the effect of modifying the plasma sheath 404. During processing, the sliding ring 150 may be precisely tilted by sending instructions to one or more of the actuating assemblies 151. For example, sending instructions to the first linear actuator 451 for raising the first pin 361 a distance ‘X’, while sending at the same time instructions to the 2^{nd} linear actuator 452 for raising the 2^{nd} pin 362 a distance ‘Y’ and not moving 3^{rd} pin 362 with the 3^{rd} linear actuator 453 results in portions of the sliding ring 150 coupling to and moving the plasma sheath 404. The controller 126 operates each of the actuating assemblies 151 in a manner that the plasma sheath along the outer edge of the substrate 101 may be uniquely controlled. For example, the sliding ring 150 might be tilted such that those areas of the substrate 101 experiencing process skew may be corrected by elevating the sliding ring 150 and those areas of the substrate 101 while other areas remain unaffected. Utilizing independent motor control for the actuating assemblies 151 process skew can be controlled. Thus, azimuthal variation of edge results can be controlled by tilting the sliding ring 150.

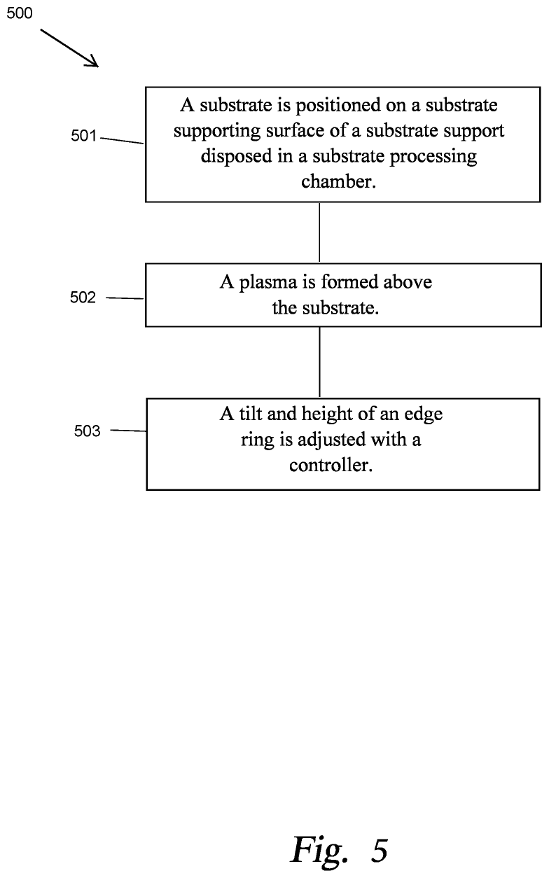

FIG. 5 is a flow diagram of a method 500 for processing a substrate. The method 500 starts at block 501 wherein a substrate is placed on a substrate support of a processing chamber for plasma processing. For example, the processing chamber may be an etch chamber. The substrate support has a sliding ring configured to move an edge ring disposed around an outer perimeter of the substrate. The sliding ring has three movement assemblies which are independently controllable. Each movement assembly has a pin. The pins are radially spaced about the sliding ring and are configured to vertically move the sliding ring, set the tilt of the sliding ring, and establish the orientation of inclination of the sliding ring. At block 502, a plasma is struck in the processing chamber for processing the substrate. The plasma has a sheath which influences processing results particularly along an outer perimeter of the substrate. Characteristics of the plasma sheath may be determined by examining process skew on a substrate processed in the processing chamber. For example, one or more areas along one region of the perimeter of the substrate may experience different processing results relative to another region of the substrate. Process skews may also be in the form of trench verticality, microloading, RIE lag, and the like. In one example, one region of the perimeter of the substrate may be etched faster than other region of the substrate. At block 503, a tilt and height of an edge ring is adjusted with a controller. A controller creates an adjustment map corresponding to the areas of along the substrate having process skew which determines an adjustment to the sliding ring in those areas. For example, the controller may look at a desired etch profile and determine a first area experiencing less etching than a processing recipe target calls for and a second area experiencing even less etching while other areas are etched at target. The controller may increment one or more movement assemblies to tilt the sliding ring as mapped. For example, the controller may tilt the sliding ring in a first area to increase etching in that area while leaving other areas unchanged. A second substrate may be processed with the sliding ring tilted in accordance to the adjustment map.

An algorithm is provided to automate the compensation for maintaining good process uniformity. The process may be monitored through post processing metrology or in-situ measurements of chamber components or substrate features for determining processing rates along the edge of the substrate. The processing rates may be mapped and compared against a recipe mapping with the controller to provide a correction algorithm for tilting the edge ring with the sliding ring to mitigate process skew. The algorithm may be computed for each substrate to maintain good process uniformity across the substrates.

Advantageously, the plasma sheath can be adjusted uniquely, or asymmetrically, along the perimeter of the substrate. The tilt of the edge ring compensates for process skew at the extreme edge of substrate, for substrates having a radius greater than 145 mm, due to edge hardware/substrate non-concentricity, the edge ring not being parallel, and/or uneven edge ring erosion. Additionally, the adjustments can made in the edge ring tilt extend the mean time between maintenance for replacing worn edge rings.

While the foregoing is directed to specific embodiments, other and further embodiments may be devised without departing from the basic scope thereof, and the scope thereof is determined by the claims that follow.

What is claimed is:

1. A method of processing a substrate, comprising:
positioning the substrate on a substrate supporting surface of a substrate support disposed in a substrate processing chamber;
forming a plasma above the substrate; and
adjusting a tilt and height of an edge ring with a controller, the controller coupled to a movement assembly having one of three linear actuators for tilting a sliding ring interfaced with the edge ring to change a direction of ions at one edge of the substrate.

2. The method of claim 1, wherein the substrate processing chamber may be an etch chamber.

3. The method of claim 1, wherein the three linear actuators are independently controllable with the controller.

4. The method of claim 3, wherein the three linear actuators have pins, the pins radially spaced equally about the sliding ring and are configured to vertically move the sliding ring.

5. The method of claim 1, further comprising
creating by the controller an adjustment map corresponding to areas along the substrate having process skew; and
determining an adjustment of the three linear actuators to move the sliding ring in the areas having process skew.

6. The method of claim 5, wherein creating by the controller an adjustment map further comprises:
obtaining at a desired etch profile from a processing recipe target;
determining a first area experiencing less etching than the processing recipe target calls for and a second area experiencing even less etching while other areas are etched at target; and
incrementing one or more of the three linear actuators to tilt the sliding ring as mapped.

7. The method of claim 6, wherein the controller may tilt the sliding ring an angle between about 0.4° and about 2.8° to elevate a first area to increase etching in that area while leaving other areas unchanged.

8. The method of claim 6, further comprising:
processing a second substrate with the sliding ring tilted in accordance to the adjustment map.

9. A process kit for a substrate processing chamber, the process kit comprising:
an edge ring configured to circumscribe a substrate in a semiconductor processing chamber;
a sliding ring positioned beneath the edge ring, the sliding ring having a top surface configured to contact a bottom surface of the edge ring; and
an actuating mechanism interfaced with a bottom surface of the sliding ring, the actuating mechanism having a first linear actuator, a second linear actuator, and a third linear actuator equally spaced along the bottom surface of the sliding ring, the actuating mechanism configured to move the sliding ring such that the edge ring may be tilted, wherein the actuating mechanism is configured to interface with a controller configured to independently operate the first linear actuator, the second linear actuator, and the third linear actuator, wherein the actuating mechanism is configured to move the first linear actuator with respect to the second linear actuator to effect a tilt to the sliding ring and the edge ring for adjusting process skew in response to an algorithm for correcting process skew.

10. The process kit of claim 9, wherein the sliding ring comprises:
a pin extending from a top surface.

11. The process kit of claim 9, wherein the sliding ring is formed from a conductive material and coupled to a waveform generator.

12. The process kit of claim 11, wherein the waveform generator is a RF power source.

13. The process kit of claim 9, wherein the sliding ring configured to tilt the edge ring an angle between about 0.4° and about 2.8°.

14. A processing chamber, comprising:
a controller configured to operate the processing chamber
a substrate support assembly configured to support a substrate, the substrate support assembly comprising:
a substrate support having a body with an electrode embedded therein;
a cathode disposed below the substrate support, the cathode configured to receive power from a waveform generator; and
a process kit supported by the substrate support assembly, the process kit comprising:
an edge ring configured to circumscribe the substrate in the processing chamber;
a sliding ring positioned beneath the edge ring, the sliding ring having a top surface configured to contact a bottom surface of the edge ring; and
an actuating mechanism interfaced with a bottom surface of the sliding ring, the actuating mechanism having a first linear actuator, a second linear actuator, and a third linear actuator equally spaced along the bottom surface of the sliding ring, the actuating mechanism configured to move the sliding ring such that the edge ring may be tilted, the actuating mechanism interfaced with the controller, the controller configured to independently operate the first linear actuator, the second linear actuator, and the third linear actuator, wherein the first linear actuator is moved with respect to the second linear actuator to effect a tilt of the sliding ring and the edge ring for adjusting process skew in response to an algorithm for correcting process skew.

15. The processing chamber of claim 14, wherein the sliding ring is formed from a conductive material.

16. The processing chamber of claim 14, further comprising:
a quartz pipe is disposed adjacent the sliding ring; and
an outer ring disposed on the quartz pipe.

17. The processing chamber of claim 16, further comprising:
a first laterally spaced gap formed between the sliding ring and the cathode, wherein the first laterally spaced gap is greater than 0 inches and is less than or equal to 0.05 inches; and
a second laterally spaced gap formed between the sliding ring and the quartz pipe, wherein the second laterally spaced gap is greater than 0 inches and is less than or equal to 0.05 inches.

18. The processing chamber of claim 17, wherein the controller is configured to tilt the sliding ring an angle between about 0.4° and about 2.8°.

19. The processing chamber of claim 18, wherein the sliding ring tilts the edge ring an angle between about 0.4° and about 2.8°.

20. The processing chamber of claim 18, wherein the sliding ring is coupled to an RF power source.
